(19) United States
(12) Patent Application Publication
(10) Pub. No.: US 2019/0198358 A1
(43) Pub. Date: Jun. 27, 2019

(54) ENVIRONMENT MAINTAINING SYSTEM AND METHOD FOR PRECISION PRODUCTION

(71) Applicants: SHENZHEN CHENZHONG TECHNOLOGY CO., LTD, ShenZhen, Guangdong (CN); REZE TECHNOLOGY CO.,LIMITED, Hong Kong (CN)

(72) Inventor: Xiaoding LI, ShenZhen, Guangdong (CN)

(21) Appl. No.: 16/092,602

(22) PCT Filed: Jul. 12, 2016
(86) PCT No.: PCT/CN2016/089786

§ 371 Date: Jan. 28, 2019

(30) Foreign Application Priority Data
Apr. 11, 2016 (CN) 201610221489.4

(51) Int. Cl. H01L 21/67; C23C 16/44; H01L 21/677

(52) U.S. Cl. CPC H01L 21/67017; C23C 16/4412; H01L 21/67115; H01L 21/67772; H01L 21/67742; H01L 21/67769

(57) ABSTRACT

The present invention discloses an environment maintenance system and method for precision production, which mainly includes a transport cassette and a manufacturing procedure processing device. The transport cassette is provided with a first environment maintenance device to maintain a positive pressure environment; the manufacturing procedure processing device is provided with a second environment maintenance device to maintain a positive pressure environment and a constant temperature/humidity environment. When the transport cassette is combined with the manufacturing procedure processing device, a receiving space of the transport cassette can be exposed to a working space of the manufacturing procedure processing device, and you can take out the product to be processed and place it in the manufacturing procedure processing device for processing, therefore, whether it is in storage, handling or in the production process, the cleanliness of the product can be effectively improved.

### BACKGROUND OF INVENTION

### 1. Field of the Invention

The present invention relates generally to a technical field of semiconductor and flat panel display, and more particularly to a system and method which can improve cleanliness in a precision production environment of a clean room level.

### 2. Description of Related Art

In recent years, high-priced panels such as Low Temperature Poly-silicon (LTPS), which are increasingly demanding for liquid crystal display panels, are ultra-thin, light in weight and low in power consumption, and can provide more vivid colors and clearer images, and it is more and more favored. However, high-priced panel production such as LTPS encounters a technical bottleneck with low yield. Wherein, a large part of this is due to the cleanliness of the clean room environment (air pollutants such as dust, acid and alkali gas, organic matter, boron, etc.), and temperature and humidity cannot meet the resolution requirements.

In the factory for manufacturing electronic components such as liquid crystal display components and semiconductor components (integrated circuits), in order to ensure the cleanliness of the products, the existing practice is to design a clean room, mainly by using the concept of air flow to form a closed type environment, the Fan Filter Unit (FFU) is used to generate clean gas to remove the dirty air inside the original environment, the fan filter unit is used to produce the clean air to bring away the dirty air in the original environment, and then the particles in the dirty air are filtered by the filter screen to achieve a dust-free environment. The air circulation mode of the whole clean room environment are all used in the return air for the clean room automatic-storage system, loading and unloading device, buffer device, substrate platform and other.

However, due to the large environment of the clean room, the airflow between the equipment interferes with each other. The products are highly susceptible to environmental cleanliness during storage, handling and production. The dust-free grade can only be maintained to Class 10 (0.3 u) (no more than 10 particles larger than 0.3 um in 1 m³ air). In the future, high-priced products such as LTPS/OLED with high resolution in the future may require Class 1 (0.1 u) cleanliness (no more than 1 particle larger than 0.1 um in 1 m³ air). Therefore, the existing technology cannot solve the problem that the production precision, temperature and humidity of LTPS/IGZO/AM-OLED and other high-precision products cannot meet the requirements.

In view of this, it is necessary to provide an environmental maintenance system and method for precision production to solve the problem of insufficient cleanliness of the existing clean room environment.

### SUMMARY OF THE INVENTION

The present invention mainly aims to provide an environment maintenance system and method for precision production, which mainly comprises a transport cassette and a manufacturing procedure processing device. The transport cassette and the manufacturing procedure processing device can maintain the cleanliness of the environment separately or after combined, whether it is in storage, handling or in the production process, it can effectively improve the cleanliness of the product, and solve the problem that the requirements for the cleanliness, the temperature and humidity of high-precision products such as LTPS/IGZO/OLED can not be met.

### Content of the Invention

To achieve the above object, the present invention provides an environment maintenance system for precision production, which comprises:
a transport cassette including an receiving space, a first movable door that can be opened and closed and a first environment maintenance device, wherein one side of the receiving space is used for bearing one product to be processed at least; the first movable door is disposed on one side of the receiving space to form a seal in the receiving space, and the first environment maintenance device maintains a positive pressure environment in the receiving space; and
a manufacturing procedure processing device including a working space, a second movable door that can be opened and closed, an internal transport unit and a second environment maintenance device, wherein the working space is used for processing the product to be processed; a second movable door is disposed at one side of the working space; when the first movable door of the transport cassette is combined and opened with the second movable door of the manufacturing procedure processing device and opened, the receiving space of the transport cassette is exposed to the working space of the manufacturing procedure processing device; the internal transport unit is used to transport back and forth the product to be processed between the receiving space and the working space; when the second movable door is closed, the working space forms a seal, and the second environment maintenance device maintains a positive pressure and a constant temperature/humidity environment in the working space.

In an embodiment of the present invention, the first environment maintenance device includes a first air filter unit that maintains a positive pressure environment in the receiving space.

In an embodiment of the present invention, the second environment maintenance device includes a second air filter unit as well as a temperature and humidity control unit, and the second air filter unit maintains a positive pressure environment in the manufacturing procedure processing device. The temperature and humidity control unit maintains a constant temperature/constant humidity environment in the manufacturing procedure processing device.

In an embodiment of the present invention, the internal transport unit is a mechanical arm.

In an embodiment of the present invention, the manufacturing procedure processing device is a chemical vapor deposition (CVD) device or an excimer laser annealing (ELA) device.

In order to achieve the above object, the present invention further provides an environment maintenance method for precision production, which comprises the following steps:
(a) providing a transport cassette, including an receiving space, a first movable door that can be opened and closed and a first environment maintenance device, wherein the receiving space bears the plural products to be processed; and the first movable door is closed to seal the receiving space, and operating the first environment maintenance device to maintain a positive pressure environment in the receiving space;
(b) providing a manufacturing procedure processing device, including a working space, a second movable door that can be opened and closed, an internal transport unit and a second environment maintenance device; and operating the second environment maintenance device to maintain a positive pressure and a constant temperature/constant humidity environment in the working space;
(c) transporting the transport cassette to the manufacturing procedure processing device by using an external transport unit;
(d) combining and opening the first movable door of the transport cassette with the second movable door of the manufacturing procedure processing device at the same time, exposing the receiving space of the transport cassette to the working space of the manufacturing procedure processing device;
(e) using the internal transport unit to take out the product to be processed in the receiving space and place it in the working space of the manufacturing procedure processing device; and
(f) operating the manufacturing procedure processing device to manufacture the product to be processed.

In an embodiment of the present invention, the first environment maintenance device includes a first air filter unit that maintains a positive pressure environment in the receiving space.

In an embodiment of the present invention, the second environment maintenance device includes a second air filter unit and a temperature and humidity control unit, and the second air filter unit maintains a positive pressure environment in the manufacturing procedure processing device. The temperature and humidity control unit maintains a constant temperature/constant humidity environment in the manufacturing procedure processing device.

In an embodiment of the present invention, the manufacturing procedure processing device is a chemical vapor deposition (CVD) device or an excimer laser annealing (ELA) device.

In an embodiment of the present invention, the internal transport unit is a mechanical arm.

In an embodiment of the present invention, the external transport unit is a transport unit of an automatic storage system.

### BRIEF DESCRIPTION OF THE DRAWINGS

FIG. 1: a schematic diagram of an environment maintenance system for precision production according to an embodiment of the present invention.

FIGS. 2A˜2F: operation schematic diagrams of an environment maintenance method for precision production according to embodiments of the present invention.

### DETAILED DESCRIPTION OF THE INVENTION

In order to make the above purposes, features and advantages of the present invention more obvious and easy to be understood, the preferred embodiments are described in detail below with reference to the accompanying drawings. Further, the directional wording mentioned in the present invention, such as “upper”, “lower”, “front”, “back”, “left”, “right”, “inside”, “outside”, “side”, etc. are used only to refer to the direction of the additional figures. Therefore, the directional wording is used to describe and understand the present invention, and not to limit the present invention.

The additional figures and the description are regarded as illustration in nature and not restrictive. In the figures, structurally similar units are denoted by the same reference numerals. In addition, for the sake of understanding and ease of description, the size and thickness of each component shown in the figures are arbitrarily illustrated, but the present invention is not limited thereto.

In the additional figures, the thickness of layers, films, panels, sections, etc. are exaggerated for clarity. In the additional figures, the thickness of layers and regions are exaggerated for the purposes of understanding and description. It will be understood that for example, when a component of a film, section or substrate is referred to as being “on” another component, the component may be directly on the mentioned another component or also an intermediate component may be present.

In the specification, the word “comprising” is to be understood to include the mentioned component, but does not exclude any other component. In addition, in the specification, “on . . . ” means that it is located above or below the target component, and does not mean that it must be on top of the gravity-based direction.

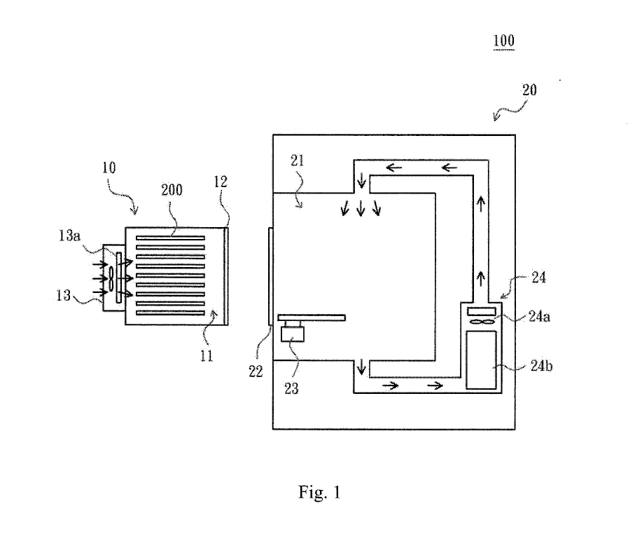

Referring to FIG. 1, which is a schematic diagram of an environment maintenance system for precision production according to an embodiment of the present invention. An environment maintenance system 100 for precision production according to an embodiment of the present invention may include: a transport cassette 10 and a manufacturing procedure processing device 20.

The transport cassette 10 includes a receiving space 11, a first movable door that can be opened and closed 12 and a first environment maintenance device 13, wherein the receiving space 11 is used to bear one product to be processed 200 at least; the first movable door 12 is disposed at one side of the receiving space 11 to form a seal for the receiving space 11, the first environment maintenance device 13 maintains a positive pressure environment in the receiving space 11.

The manufacturing procedure processing device 20 includes a working space 21, a second movable door that can be opened and closed 22, an internal transport unit 23 and a second environment maintenance device 24, wherein the working space 21 is used to process the product to be processed 200; the second movable door 22 is disposed at one side of the working space 21; when the first movable door 12 of the transport cassette 10 is combined and opened with the second movable door 22 of the manufacturing procedure processing device 20, the receiving space 11 of the transport cassette 10 is exposed to the working space 21 of the manufacturing procedure processing device 20; the internal transport unit 23 is used to transport back and forth the product to be processed 200 between the receiving space 11 and the working space 21; when the second movable door 21 is closed, the working space 21 forms a seal, and the second environment maintenance device 24 maintains a positive pressure and a constant temperature/humidity environment in the working space 21.

In an embodiment of the present invention, the first environment maintenance device 13 includes a first air filter unit 13a that maintains a positive pressure environment in the receiving space 11. In an embodiment of the present invention, the air filter unit 13a is, for example, a fan filter unit (FFU), the FFU maintains a power-on operation state, and the FFU maintains a positive pressure in the transport cassette 10, for example, the dust on the surface of the product 200 (such as a glass substrate of a liquid crystal panel or a substrate of a semiconductor) is continuously blown out from the transport cassette 10.

In another possible embodiment of the present invention, the first air filter unit 13a is, for example, a high-pressure pump unit (HPU) and a chemical filter unit.

In an embodiment of the present invention, the second environment maintenance device 24 includes a second air filter unit 24a and a temperature and humidity control unit 24b. The second air filter unit 24a maintains a positive pressure environment in the manufacturing procedure processing device 20. The temperature and humidity control unit 24b maintains a constant temperature/humidity environment in the manufacturing procedure processing device 20. The second air filter unit 24a is, for example, a high efficiency particulate air filter (HEPA).

In an embodiment of the present invention, the internal transport unit 23 is a mechanical arm, roller or caterpillar track and other transport devices.

In an embodiment of the present invention, the manufacturing procedure processing device 20 is, for example, a chemical vapor deposition (CVD) device, and the chemical vapor deposition (CVD) in the LTPS process is the chemical reaction to form a film on a substrate through vapor or on a surface of a substrate. When preparing a film material by chemical vapor deposition, in order to synthesize a good film material, it is necessary to control the composition of the reaction gas, the working gas pressure, the substrate temperature, the gas flow rate and the purity of the material gas. Through the design method of the present patent, the CVD process can effectively solve the problem of high foreign matter before film formation.

In another embodiment of the present invention, the manufacturing procedure processing device 20 is, for example, an excimer laser annealing (ELA) device, and a key process of the LTPS is the excimer laser annealing (ELA) technology, that is, using the excimer laser as a heat source to convert the amorphous silicon structure into polysilicon structure with higher resolution and faster reaction speed. The effects of environmental air pollutants on the process, such as dust, acid and alkali gas, organic matter and boron, are especially obvious. Through the present patent design, ELA process can effectively solve the abnormal problem that the acid and alkali gas and organic gas affect the pattern.

However, it is not limited to the above embodiment. In other embodiments, the manufacturing procedure processing device 20 can also be used in other semiconductor manufacturing procedure, or optoelectronic manufacturing procedure and other precision manufacturing procedure.

In an embodiment of the present invention, the manufacturing procedure processing device 20 may be sealed by sealing the periphery and the upper and lower sides of the device without isolation, and only retaining the inlet and outlet of the transport cassette 10, as described above second movable door 22. In addition, preferably, the manufacturing procedure processing device 20 is disposed to feed the ultra-clean constant-temperature and constant-humidity air from above side and to evacuate the air with low cleanliness from below, so that the manufacturing procedure processing device 20 always maintains a constant temperature and humidity and ultra clean state.

In summary, an environment maintenance system 100 for precision production of an embodiment of the present invention can be used to improve the cleanliness of a precision production environment (such as a clean room), whether in storage, handling or in the production process, in addition to relying on the return air system of the entire factory environment, a small environment used the product is added with an independent return air system. Moreover, the present invention can separately design a small environment added with an independent return air system for certain processes in the factory that require extremely high product cleanliness and temperature and humidity.

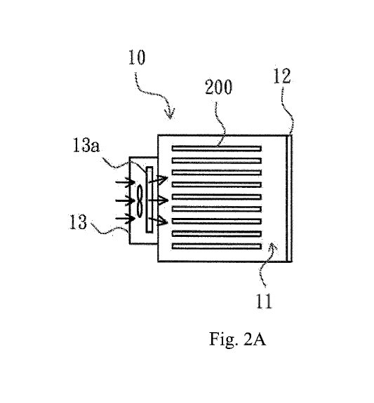

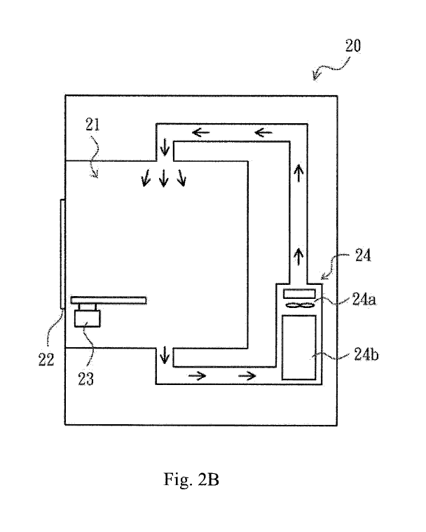

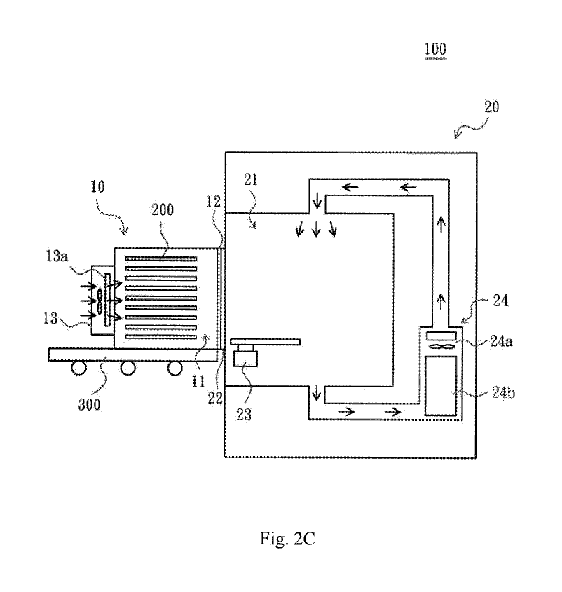

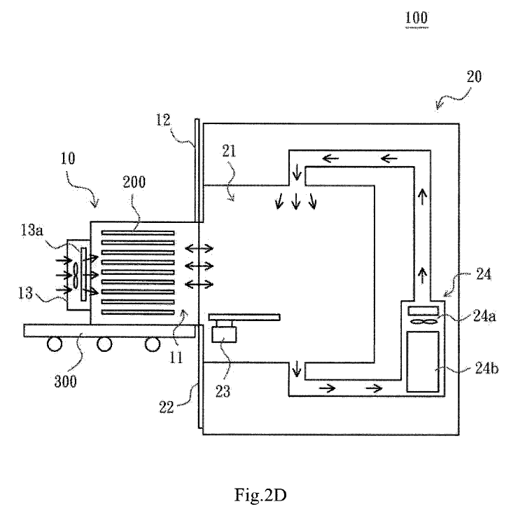

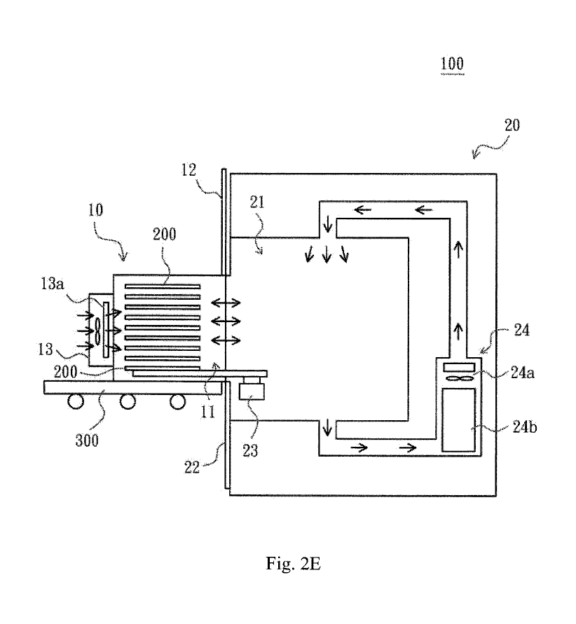

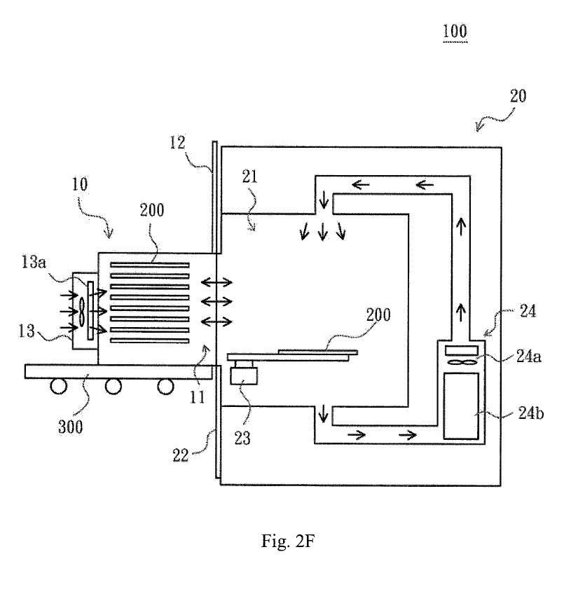

Referring to FIGS. 2A-2F, which are the operation schematic diagrams of an environment maintenance method for precision production according to an embodiment of the present invention, an embodiment of the present invention provides an environment maintenance method for precision production, which comprises the following steps:
(a) As shown in FIG. 2A, a transport cassette 10 is provided, which includes a receiving space 11, a first movable door that can be opened and closed 12 and a first environment maintenance device 13, wherein the receiving space 11 bears the plural products to be processed 200; the first movable door 12 is closed to form a seal for the receiving space 11, and the first environment maintenance device 13 is operated to maintain a positive pressure environment in the receiving space 11.
(b) As shown in FIG. 2B, a manufacturing procedure processing device 20 is provided, which includes a working space 21, a second movable door 22, an internal transport unit 23 and a second environment maintenance device 24; and the second environment maintenance device 24 is operated to maintain a positive pressure and a constant temperature/humidity environment in the working space 21.
(c) As shown in FIG. 2C, the transport cassette 10 is transported to the manufacturing procedure processing device 20 by using an external transport unit 300.
(d) As shown in FIG. 2D, the first movable door 12 of the transport cassette 10 is simultaneously opened with the second movable door 22 of the manufacturing procedure processing device 20, while the receiving space 11 of the transport cassette 10 is exposed in the working space 21 of the manufacturing procedure processing device 20.
(e) As shown in FIG. 2E, the product to be processed 200 in the receiving space 11 is taken out by the internal transport unit 23 and placed in the working space 21 of the manufacturing procedure processing device 20.
(f) As shown in FIG. 2F, the manufacturing procedure processing device 20 is operated to perform a processing operation for the product to be processed 200.

Preferably, the external transport unit 300 is a transport unit of an automatic storage system.

In addition, after the processing operation is completed, the product 200 in the working space 21 of the manufacturing procedure processing device 20 is sent back to the receiving space 11 of the transport cassette 10 by using the internal transport unit 23, and then a next product to be processed 200 is taken out for performing a processing operation. When all the products 200 in the transport cassette 10 are completed, the first movable door 12 of the transport cassette 10 and the second movable door 22 of the manufacturing procedure processing device 20 can be closed. The transport case 10 is removed away from the manufacturing procedure processing device 20 by the external transport unit 300.

Through said environment maintenance system and method for precision production of the present invention, the product is purified and treated for air pollutants (dust, acid and alkali gas, organic boron, etc.) and kept with constant temperature and constant humidity during the storage, handling and production process. Therefore, it can solve the problem that the production cleanliness, temperature and humidity of LTPS/IGZO/AM-OLED and other high-precision products cannot meet the requirements. The cleanliness of the product can be significantly improved from class 10 (0.3 u) to class 1 (0.1 u) through the transport cassette 10 and the manufacturing procedure processing device 20. Moreover, the environment of each device in the system is independent, the cleanliness, temperature and humidity are independently controllable, and an independent return air system can be added in the design separately for a small environment of some processes with high requirements for product cleanliness and temperature and humidity. It can achieve the requirement of both cleanliness and cost savings.

The wordings of “in some embodiments” and “in various embodiments” are used repeatedly, the wordings generally do not mean the same embodiment; but it can also mean the same embodiment. The wordings of “comprise”, “has” and “include” are synonymous, unless the meaning of the text is displayed before and after.

Although the embodiments of various methods, devices, and systems have been described herein, the covered scope of the present invention is not limited thereto. Instead, the content of the present invention covers all methods, the devices, the systems and the manufactured goods reasonably in the scope of the claims, the scope of the claims should be interpreted in accordance with the principles of the claimed scope of patent application. For example, although the examples of the system shown above include the software or firmware that can be implemented by hardware, but it should be understood that such systems are merely exemplary examples and should be construed as restrictive examples. In particular, any or all of the disclosed hardware, software, and/or firmware components can be specifically embodied as hardware, specifically embodied as software, specifically embodied as firmware, or some combination of hardware, software, and/or firmware.

The present invention has been described by said embodiments, but said embodiments are merely examples for implementing the present invention. It is to be noted that the disclosed embodiments do not limit the scope of the present invention. Conversely, modifications and equalization for the spirit and scope of the claim are included in the scope of the present invention.

1. An environment maintenance system for precision production comprises:
a transport cassette, including a receiving space, a first movable door that can be opened and closed, and a first environment maintenance device, wherein the receiving space is used for bearing one product to be processed at least; one side disposed in the receiving space by the first movable door forms a seal in the receiving space, the first environment maintenance device maintains a positive pressure environment in the receiving space; and
a manufacturing procedure processing device, including a working space, a second movable door that can be opened and closed, an internal transport unit and a second environment maintenance device, wherein the working space is used for processing the product to be processed; the second movable door is disposed at one side of the working space; when a first movable door of the transport cassette is combined and opened with the second movable door of the manufacturing procedure processing device; the receiving space of the transport cassette is exposed in a working space of the manufacturing procedure processing device; the internal transport unit is used to transport back and forth the product to be processed between the receiving space and the working space; when the second movable door is closed, the working space forms a seal, and the second environment maintenance device maintains a positive pressure and a constant temperature/humidity environment in the working space.

2. The system defined in claim 1, wherein the first environment maintenance device includes a first air filter unit that maintains a positive pressure environment in the receiving space.

3. The system defined in claim 1, wherein the second environment maintenance device includes a second air filter unit and a temperature and humidity control unit, the second air filter unit maintains a positive pressure environment in the manufacturing procedure processing device, and the temperature and humidity control unit maintains a constant temperature/constant humidity environment in the manufacturing procedure processing device.

4. The system defined in claim 1, wherein the internal transport unit is a mechanical arm.

5. The system defined in claim 1, wherein the manufacturing procedure processing device is a chemical vapor deposition (CVD) device or an excimer laser annealing (ELA) device.

6. An environment maintenance method for precision production, characterized in that it comprises the following steps:
(a) providing a transport cassette, including a receiving space, a first movable door that can be opened and closed, and a first environment maintenance device, wherein the receiving space bears the plural products to be processed; closing the first movable door to seal the receiving space, and operating the first environment maintenance device to maintain a positive pressure environment in the receiving space;
(b) providing a manufacturing procedure processing device, including a working space, a second movable door that can be opened and closed, an internal transport unit and a second environment maintenance device; and operating the second environment maintenance device to maintain a positive pressure and constant temperature/constant humidity environment in the working space;
(c) using a external transport unit to transport the transport cassette to the manufacturing procedure processing device;
(d) the first movable door of the transport cassette combined and opened simultaneously with the second movable door of the manufacturing procedure processing device, exposing the receiving space of the transport cassette to the working space of the manufacturing procedure processing device;
(e) using the internal transport unit to take out the product to be processed in the receiving space and place it in the working space of the manufacturing procedure processing device; and
(f) operating the manufacturing procedure processing device to process the product to be processed.

7. The method defined in claim 6, wherein the first environment maintenance device includes a first air filter unit that maintains a positive pressure environment in the receiving space.

8. The method defined in claim 6, wherein the second environment maintenance device includes a second air filter unit and a temperature and humidity control unit, the second air filter unit maintains a positive pressure environment in the manufacturing procedure processing device, and the temperature and humidity control unit maintains a constant temperature/constant humidity environment in the manufacturing procedure processing device.

9. The method defined in claim 6, wherein the manufacturing procedure processing device is a chemical vapor deposition (CVD) device or an excimer laser annealing (ELA) device.

10. The method defined in claim 6, wherein the internal transport unit is a mechanical arm; and the external transport unit is a transport unit of an automatic storage system.

11. An environment maintenance system for precision production comprises: a transport cassette including a receiving space, a first movable door that can be opened and closed, and a first environment maintenance device, wherein the receiving space is used for bearing one product to be processed at least; the first movable door is disposed at one side of the receiving space to seal the receiving space, the first environment maintenance device maintains a positive pressure environment in the receiving space; and a manufacturing procedure processing device includes a working space, a second movable door that can be opened and closed, an internal transport unit and a second environment maintenance device, wherein the working space is used to process the product to be processed; The second movable door is disposed at one side of the working space; when a first movable door of the transport cassette is combined and opened with a second movable door of the manufacturing procedure processing device, the receiving space of the transport cassette is exposed to the working space of the manufacturing procedure processing device; the internal transport unit is used to transport back and forth the product to be processed between the receiving space and the working space; when the second movable door is closed, a seal is formed in the working space, and the second environment maintenance device maintains a positive pressure and a constant temperature/humidity environment in the working space; wherein the first environment maintenance device includes a first air filter unit that maintains a positive pressure environment in the receiving space, the first air filter unit is a fan filter unit, a high pressure pump unit or a chemical filter unit; the internal transport unit is a mechanical arm, a roller or a crawler.
